(19) United States
(12) Patent Application Publication
(10) Pub. No.: US 2025/0149287 A1
(43) Pub. Date: May 8, 2025

(54) Ion Milling Device

(71) Applicant: Hitachi High-Tech Corporation, Minato-ku, Tokyo (JP)

(72) Inventors: Shota AIDA, Tokyo (JP); Hisayuki TAKASU, Tokyo (JP); Atsushi KAMINO, Tokyo (JP)

(21) Appl. No.: 18/838,013

(22) PCT Filed: Mar. 10, 2022
(86) PCT No.: PCT/JP2022/010622

§ 371 Date: Aug. 13, 2024

(51) Int. Cl. H01J 37/08; H01J 37/20; H01J 37/304

(52) U.S. Cl. CPC H01J 37/08; H01J 37/20; H01J 37/304; H01J 2237/20207

(57) ABSTRACT

A change amount of a frequency of a crystal resonator 40 per unit time is increased. An ion milling device 100 includes an ion source 20 configured to emit an ion beam, a sample stage 30 configured to allow a sample to be placed thereon, a first inclining mechanism 31 connected to the sample stage 30 and configured to adjust an inclined angle of the sample stage 30, the crystal resonator 40, an oscillation circuit 8 electrically connected to the crystal resonator 40 and configured to vibrate the crystal resonator 40 and receive a frequency output from the crystal resonator 40, a second inclining mechanism 41 connected to the crystal resonator 40 and configured to adjust an inclined angle of the crystal resonator 40, and a control unit 2. The control unit 2 is electrically connected to the ion source 20, the first inclining mechanism 31, the oscillation circuit 8, and the second inclining mechanism 41, and is configured to control operations of the ion source 20, the first inclining mechanism 31, the oscillation circuit 8, and the second inclining mechanism 41.

### TECHNICAL FIELD

The present invention relates to an ion milling device, and particularly relates to an ion milling device including a crystal resonator.

### BACKGROUND ART

In recent years, ion milling processing using an ion beam has been used as a method for preparing a sample without stress. Such a sample is prepared as an observation target of an electron microscope such as a scanning electron microscope (SEM) or a transmission electron microscope (TEM), and is made of, for example, a metal, a semiconductor, a glass, or a ceramic.

An ion milling device is a device that emits an unfocused ion beam to the sample and uses a sputtering phenomenon to knock off atoms on a surface of the sample. Accordingly, polishing of the surface of the sample can performed without stress, and an internal structure of the sample can be exposed. The polished surface of the sample or the internal structure of the sample is an observation surface of the SEM or the TEM.

For example, PTL 1 discloses an ion milling device in which a crystal resonator that is constantly oscillated is disposed in the vicinity of a sample. PTL 1 further discloses a method of obtaining a processing amount of the sample based on a change amount of a frequency according to an amount of sputtering particles adhering to the crystal resonator.

### CITATION LIST

### Patent Literature

PTL 1: WO2021/038650

### SUMMARY OF INVENTION

### Technical Problem

When the above-described method using the crystal resonator is used, a scattering direction of the sputtering particles changes according to an emission angle of the ion beam with respect to the sample. Therefore, in order to increase the change amount of the frequency of the crystal resonator per unit time and to improve the time resolution for the change amount of the frequency, it is important that the crystal resonator is located at a position where more sputtering particles can adhere. If such a technique can be established, for example, when the processing amount of the sample reaches a target processing amount, the emission of the ion beam can be stopped with high accuracy.

Other problems and novel features will be clarified according to the description of the present specification and the accompanying drawings.

### Solution to Problem

An outline of a representative one among embodiments disclosed in the present application will be briefly described as follows.

An ion milling device according to one embodiment includes: an ion source configured to emit an ion beam; a sample stage configured to allow a sample to be placed thereon; a first inclining mechanism connected to the sample stage and configured to adjust an inclined angle of the sample stage; a crystal resonator; an oscillation circuit electrically connected to the crystal resonator and configured to vibrate the crystal resonator and receive a frequency output from the crystal resonator; a second inclining mechanism connected to the crystal resonator and configured to adjust an inclined angle of the crystal resonator; and a control unit electrically connected to the ion source, the first inclining mechanism, the oscillation circuit, and the second inclining mechanism and configured to control operations of the ion source, the first inclining mechanism, the oscillation circuit, and the second inclining mechanism.

### Advantageous Effects of Invention

According to one embodiment, it is possible to increase the change amount of the frequency of the crystal resonator per unit time.

### BRIEF DESCRIPTION OF DRAWINGS

FIG. 1 is a schematic view showing an ion milling device according to Embodiment 1.

FIG. 2 is a schematic view showing the ion milling device according to Embodiment 1.

FIG. 3 is a schematic view showing an ion source according to Embodiment 1.

FIG. 4 is a schematic view showing the ion source, a sample stage, and a crystal resonator according to Embodiment 1.

FIG. 5 is a schematic view showing the ion source, the sample stage, and the crystal resonator according to Embodiment 1.

FIG. 6 is a flowchart showing a method of ion milling processing according to Embodiment 1.

FIG. 7 is a schematic view showing a sample stage and a crystal resonator according to Embodiment 2.

FIG. 8 is a flowchart showing a method of ion milling processing according to Embodiment 2.

FIG. 9 is a flowchart showing a method of ion milling processing according to a modification of Embodiment 2.

FIG. 10 is a schematic view showing a sample stage and a crystal resonator according to the modification of Embodiment 2.

FIG. 11 is a schematic view showing the sample stage and the crystal resonator according to the modification of Embodiment 2.

FIG. 12 is a schematic view showing an ion milling device according to Embodiment 3.

### DESCRIPTION OF EMBODIMENTS

Hereinafter, embodiments will be described in detail with reference to the drawings. In all the drawings illustrating the embodiments, members having the same function are denoted by the same reference numeral, and the repeated description thereof is omitted. In the following embodiments, the description of the same or similar parts will not be repeated in principle unless particularly necessary.

An X direction, a Y direction, and a Z direction to be described in the present application intersect with one another and are orthogonal to one another.

### Embodiment 1

### <Structure of Ion Milling Device>

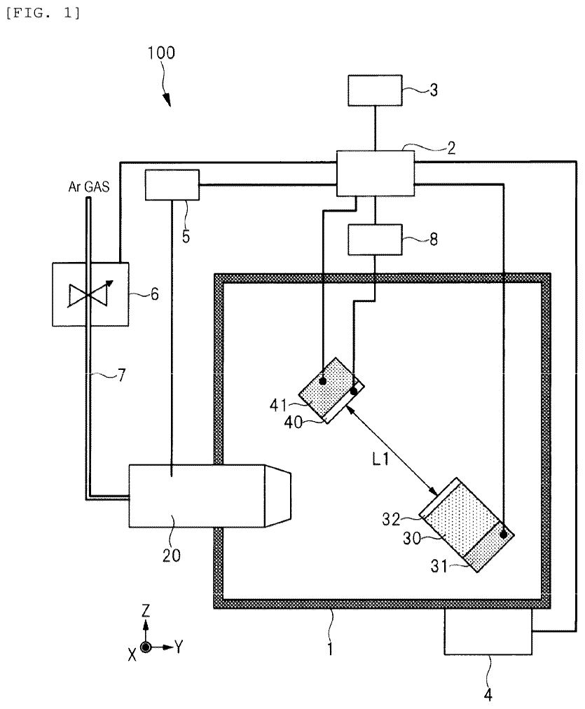

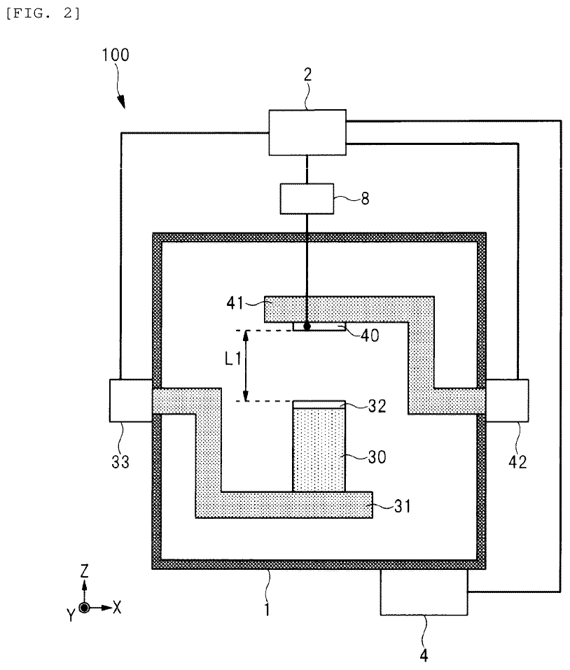

An ion milling device 100 according to Embodiment 1 will be described below with reference to FIGS. 1 to 5. The ion milling device 100 is used as a pretreatment device for preparing a sample to be observed by an electron microscope such as an SEM or a TEM. FIG. 1 is a schematic view of main parts of the ion milling device 100 as viewed from the X direction, and FIG. 2 is a schematic view of the main parts of the ion milling device 100 as viewed from the Y direction.

As shown in FIG. 1, the ion milling device 100 mainly includes a sample chamber 1, a control unit 2, a display unit 3, a vacuum exhaust unit 4, a high voltage unit 5, a gas supply unit 6, a pipe 7, an oscillation circuit 8, an ion source 20, a sample stage 30, a first inclining mechanism 31 for a sample stage, a crystal resonator 40, and a second inclining mechanism 41 for a crystal resonator.

The control unit 2 is electrically connected to the vacuum exhaust unit 4, the ion source 20 (high voltage unit 5), the gas supply unit 6, the oscillation circuit 8, the first inclining mechanism 31, and the second inclining mechanism 41, and can control operations thereof. The display unit 3 is electrically connected to the control unit 2. Various types of information performed by the ion milling device 100 are displayed on the display unit 3. A user can confirm the various types of information on the display unit 3 and can input various instructions to the control unit 2.

The ion source 20 that can emit an ion beam, the sample stage 30 on which a sample can be placed, the first inclining mechanism 31, the crystal resonator 40, and the second inclining mechanism 41 are provided inside the sample chamber 1. The sample stage 30 includes a sample table 32 as a part of members implementing the sample stage 30. The sample table 32 is implemented by a sample holder or the like that can place the sample and fix the sample. In the present application, the description will be made assuming that the sample is placed on the sample stage 30 in the same meaning as placing the sample on the sample table 32.

By driving the vacuum exhaust unit 4, an inside of the sample chamber 1 can be adjusted to pressure from atmospheric pressure to high vacuum (1.0×10⁻³ Pa or less). During the emission of the ion beam, the inside of the sample chamber 1 is kept at the high vacuum. Therefore, it is possible to emit the stable ion beam to the sample without being affected by gases in the atmosphere.

In the gas supply unit 6, a flow rate of an argon (Ar) gas to be supplied to the ion source 20 via the pipe 7 is adjusted. The argon gas supplied from the gas supply unit 6 to the ion source 20 is ionized by the high voltage unit 5 and is emitted from the ion source 20 to the sample placed on the sample stage 30 as a non-focused ion beam.

As shown in FIGS. 1 and 2, the first inclining mechanism 31 is connected to the sample stage 30 and is provided to adjust an inclined angle of the sample stage 30. A motor 33 is attached to the first inclining mechanism 31. The second inclining mechanism 41 is connected to the crystal resonator 40 and is provided to adjust an inclined angle of the crystal resonator 40. A motor 42 is attached to the second inclining mechanism 41. A distance between the sample stage 30 and the crystal resonator 40 is maintained at, for example, a distance L1.

The motor 33 and the motor 42 are electrically connected to the control unit 2, and a rotation speed of each of the motor 33 and the motor 42 can be individually controlled by the control unit 2. That is, when the control unit 2 drives the motor 33 and the motor 42, the first inclining mechanism 31 and the second inclining mechanism 41 move in a Y-Z plane, and the sample stage 30 and the crystal resonator 40 are inclined in the Y-Z plane.

A method of moving the first inclining mechanism 31 and the second inclining mechanism 41 is not limited to the control of the rotation speed of each of the motor 33 and the motor 42. For example, inclination sensors may be provided on the first inclining mechanism 31 and the second inclining mechanism 41, and the inclined angles may be determined with reference to the inclination sensors. Although the motor 33 and the motor 42 are used here, the first inclining mechanism 31 and the second inclining mechanism 41 may be provided with scales, and the first inclining mechanism 31 and the second inclining mechanism 41 may be manually moved by the user with reference to the scales.

The oscillation circuit 8 is electrically connected to the crystal resonator 40, vibrates the crystal resonator 40, and receives a frequency output from the crystal resonator 40. The frequency received by the oscillation circuit 8 is transmitted to the control unit 2.

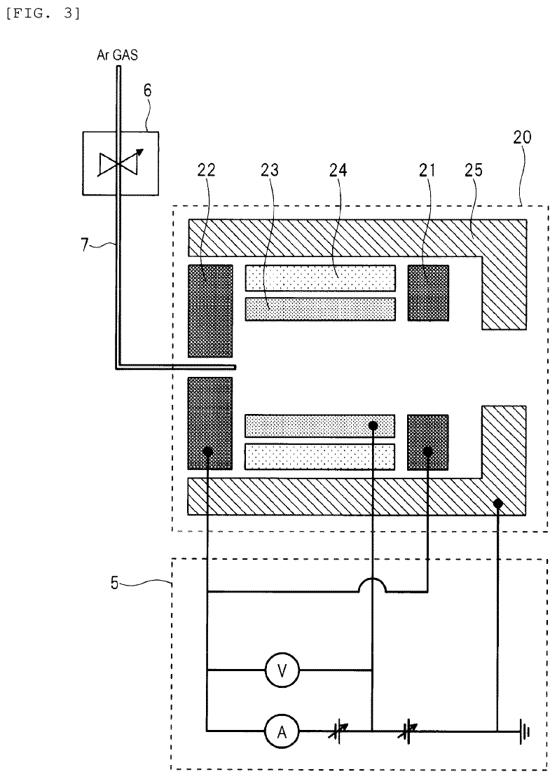

FIG. 3 shows a detailed structure of the ion source 20 using the Penning method.

As shown in FIG. 3, the ion source 20 includes a first cathode electrode 21, a second cathode electrode 22, an anode electrode 23, a permanent magnet 24, and an acceleration electrode 25. The ion source 20 is electrically connected to the control unit 2 via the high voltage unit 5, and various voltages are applied to each electrode from the high voltage unit 5.

An argon gas is supplied from the gas supply unit 6 into the ion source 20 via the pipe 7. The first cathode electrode 21 and the second cathode electrode 22 are disposed facing each other, and the anode electrode 23 is disposed between the first cathode electrode 21 and the second cathode electrode 22. Electrons are generated when a discharge voltage Vd is applied from the high voltage unit 5 between the first cathode electrode 21 and the anode electrode 23 and between the second cathode electrode 22 and the anode electrode 23. A Lorentz force acts on the electrons by the permanent magnet 24 disposed inside the ion source 20, causing the electrons to move in a spiral manner, resulting in a longer path.

When the electrons collide with the argon gas, argon ions are generated. An acceleration voltage Va is applied between the anode electrode 23 and the acceleration electrode 25 from the high voltage unit 5, and the generated argon ions are extracted by the acceleration electrode 25 and are discharged outside the ion source 20 as the ion beam.

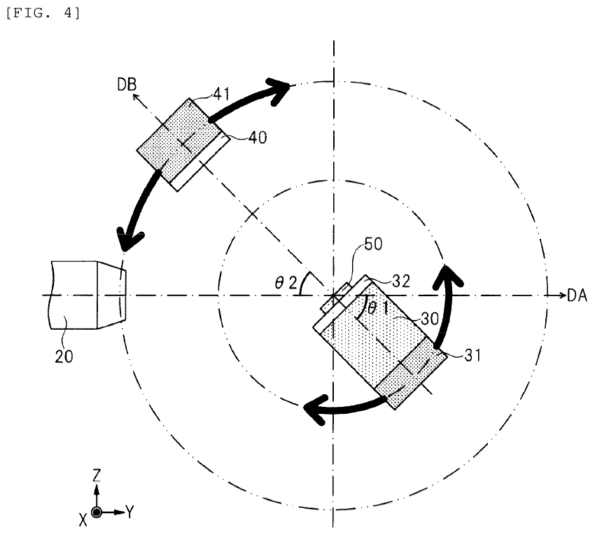

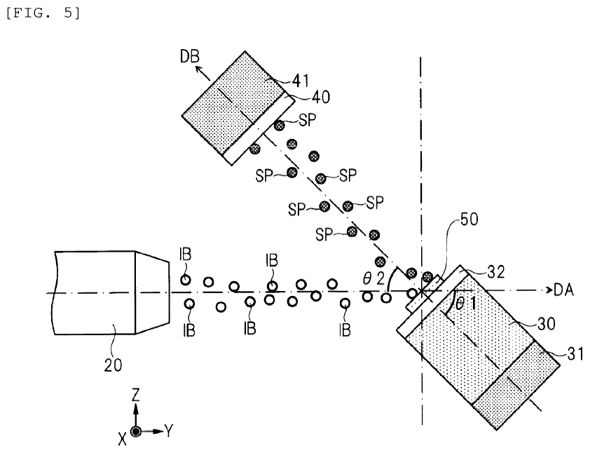

An arrangement relationship and a movement direction of the first inclining mechanism 31 and the second inclining mechanism 41 will be described below with reference to FIGS. 4 and 5. In FIGS. 4 and 5, a state in which the sample 50 is placed on the sample stage 30 is shown. The sample 50 is, for example, a metal, a semiconductor, a glass, a ceramic, or the like, or a structure implemented by a composite thereof.

As shown in FIG. 4, the first inclining mechanism 31 and the second inclining mechanism 41 can rotate around a direction (X direction) perpendicular to a central axis DA (Y direction) of the ion beam as a rotation axis. Here, the rotation axis of the first inclining mechanism 31 and the rotation axis of the second inclining mechanism 41 are coaxial. When the first inclining mechanism 31 rotates and moves, the sample stage 30 is inclined. When the second inclining mechanism 41 rotates and moves, the crystal resonator 40 is inclined. In FIG. 4, an inclined angle θ1 of the sample stage 30 with respect to the central axis DA of the ion beam and an inclined angle θ2 of the crystal resonator 40 with respect to the central axis DA of the ion beam are shown.

As shown in FIG. 5, when an ion beam IB is emitted from the ion source 20 to the sample 50 at the time of processing the sample 50, sputtering particles SP are generated from the sample 50 by the sputtering phenomenon. A scattering direction of the sputtering particles SP depends on the inclined angle θ1 of the sample stage 30.

That is, since an angle distribution of the scattering direction of the sputtering particles SP follows the Lambert's cosine law, the sputtering particles SP adhere to the crystal resonator 40 in the largest amount on a perpendicular line DB perpendicular to a surface of the sample 50 (surface of sample stage 30). Therefore, when the sample 50 is placed on the sample stage 30, the control unit 2 adjusts the inclined angle θ2 of the crystal resonator 40 by the second inclining mechanism 41 such that the crystal resonator 40 is located on the perpendicular line DB perpendicular to the surface of the sample 50.

As described above, it is desirable to set the inclined angle θ2 in consideration of the inclined angle θ1 set at a predetermined angle before the sample 50 is processed. It is most preferable that the sample 50 is disposed at coordinates where the central axis DA of the ion beam IB intersects with the perpendicular line DB.

However, due to an assembly error or a control error of the ion milling device 100, the sample 50 may not be accurately disposed at the coordinates. In this case, a three-direction mechanism capable of moving the ion source 20 or the sample stage 30 in the X direction, the Y direction, and the Z direction may be provided, and the three-direction mechanism may be adjusted such that a position of the sample 50 is at the above-described coordinates.

After the ion beam IB is emitted, when a part of the generated sputtering particles SP adheres to the crystal resonator 40, a mass of the entire crystal resonator 40 changes by an adhesion amount Δw. When the frequency output from the crystal resonator 40 to the oscillation circuit 8 changes according to the adhesion amount Δw of the sputtering particles SP and reaches a target value frequency, the control unit 2 controls the ion source 20 to stop the emission of the ion beam IB. That is, the control unit 2 determines the case in which the frequency reaches the target value frequency as a state in which the processing on the sample 50 is ended, and automatically stops the emission of the ion beam IB.

In order to determine the end of the processing on the sample 50 based on the target value frequency, data of the structure implementing the sample 50 and data regarding which frequency is used as the target value frequency to determine that the processing is ended when the sample 50 is subjected to the ion milling processing at the distance L1 are recorded in the control unit 2 in advance. The control unit 2 can compare the recorded target value frequency with the actually acquired frequency, and can automatically determine whether the processing on the sample 50 may be ended.

As described above, the sputtering particles SP adhere to the crystal resonator 40 in the largest amount on the perpendicular line DB perpendicular to the surface of the sample 50. Therefore, by adjusting the inclined angle θ2 and making the inclined angle θ2 the same as the inclined angle θ1, it is possible to increase the adhesion amount per unit time Δw/t of the sputtering particles SP. Therefore, it is possible to provide the ion milling device 100 in which the time resolution for the change amount of the frequency is increased.

The inclined angle θ2 may not be exactly the same as the inclined angle θ1, and may be slightly shifted from the inclined angle θ1. Even in this case, the adhesion amount per unit time Δw/t can be sufficiently increased as long as the crystal resonator 40 is not detached from the perpendicular line DB and is located on the perpendicular line DB.

Since the crystal resonator 40 is constantly controlled by the oscillation circuit 8, the change amount of the frequency is monitored constantly by the control unit 2 during the emission of the ion beam IB. The user can confirm the change amount of the frequency on the display unit 3.

During the emission of the ion beam IB, the inclined angle θ2 may not always be constant and may be changed. During the emission of the ion beam IB, the control unit 2 can change the inclined angle θ2 of the crystal resonator 40 by the second inclining mechanism 41 according to a change in the frequency output from the crystal resonator 40 to the oscillation circuit 8. For example, during the emission of the ion beam IB, a state of a processing surface of the sample 50 may change, the scattering direction of the sputtering particles SP may change, and the adhesion amount Δw may be in an insufficient situation. In this case, the inclined angle θ2 can be changed to increase the adhesion amount Δw by the user transmitting an instruction to the control unit 2.

### <Processing Method of Sample>

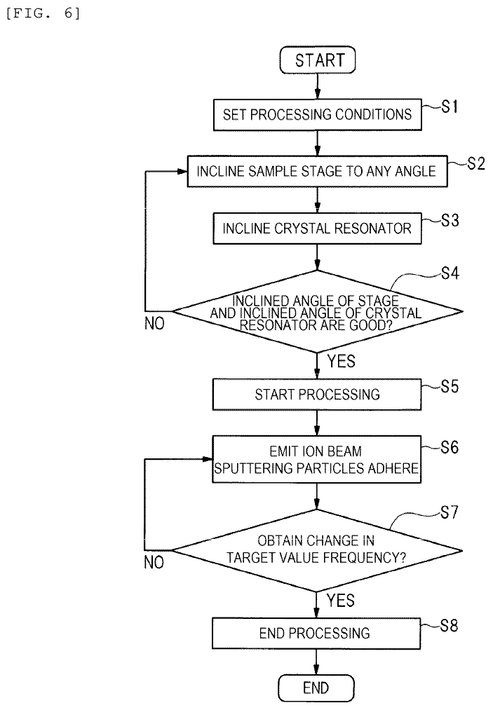

A processing method of the sample 50 using the ion milling device 100 according to Embodiment 1 will be described below with reference to a flowchart of FIG. 6.

First, in step S1, processing conditions of the ion milling device 100 are set. The processing conditions include an acceleration voltage of the ion source 20, a discharge voltage of the ion source 20, a supply amount of the argon gas, a position of the sample stage 30, the data of the structure implementing the sample 50, and a setting of the target value frequency regarding as a processing end. Next, the inside of the sample chamber 1 is made into high vacuum, the sample 50 is transferred from the outside of the sample chamber 1, and the sample 50 is placed on the sample stage 30.

In step S2, the control unit 2 moves the first inclining mechanism 31 via the motor 33 to incline the sample stage 30 until the inclined angle θ1 is attained.

In step S3, the control unit 2 moves the second inclining mechanism 41 via the motor 42 to incline the crystal resonator 40 until the inclined angle θ2 is attained. Here, the control unit 2 adjusts the inclined angle θ2 of the crystal resonator 40 by the second inclining mechanism 41 such that the crystal resonator 40 is located on the perpendicular line DB perpendicular to the surface of the sample 50.

In step S4, it is confirmed whether the inclined angle θ1 and the inclined angle θ2 are good. For example, it is confirmed whether the inclined angle θ2 is the same as the inclined angle θ1. If correction is necessary (NO), the processing returns to step S2, and the adjustment is performed again. If correction is not necessary (YES), the next step is step S5, and the ion milling processing on the sample 50 is started.

In step S6, the ion beam IB is emitted from the ion source 20 to the sample 50. Accordingly, the sputtering particles SP are generated from the sample 50, and a part of the sputtering particles SP adhere to the crystal resonator 40. The frequency output from the crystal resonator 40 to the oscillation circuit 8 changes according to the adhesion amount Δw of the sputtering particles SP.

In step S7, it is confirmed whether the target value frequency is obtained. The control unit 2 determines the frequency received from the oscillation circuit 8, and when the frequency reaches the target value frequency set in advance, the control unit 2 controls the ion source 20 to stop the emission of the ion beam IB. The stop of the emission of the ion beam IB may be automatically performed by the control unit 2, and may be performed by the user referring to the change amount of the frequency displayed on the display unit 3.

If the target value frequency is not obtained (NO), the processing returns to step S6, and the emission of the ion beam is continued. If the target value frequency is obtained (YES), the next step is step S8, and the ion milling processing is ended. Thereafter, the sample 50 is transferred from the sample stage 30 to the outside of the sample chamber 1.

### Embodiment 2

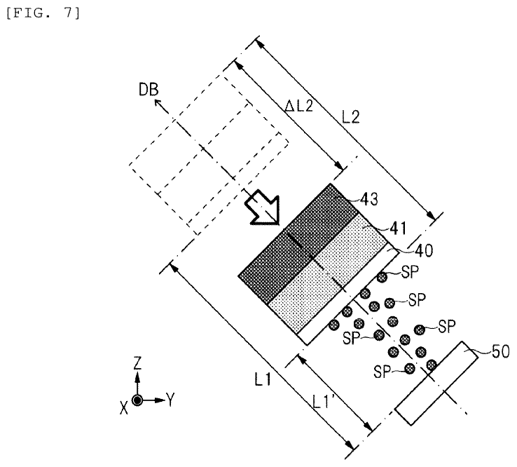

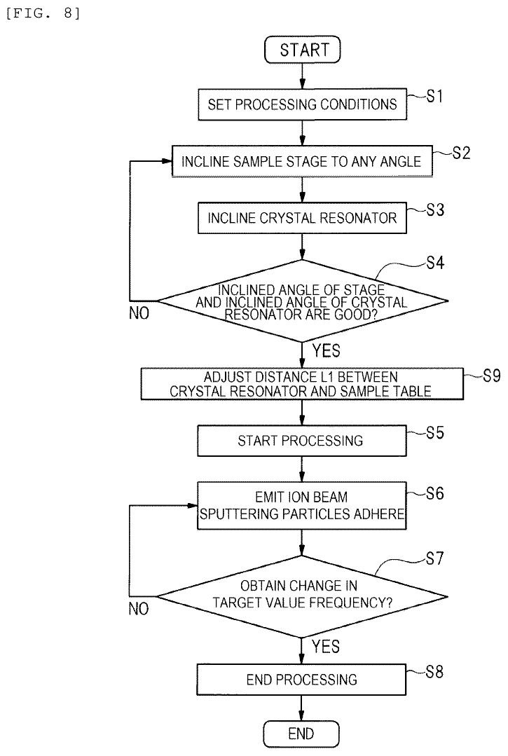

The ion milling device 100 according to Embodiment 2 will be described below with reference to FIGS. 7 and 8. In the following description, differences from Embodiment 1 will be mainly described, and descriptions of points overlapping those of Embodiment 1 will be omitted.

As shown in FIG. 7, in Embodiment 2, not only the second inclining mechanism 41 but also a movement mechanism 43 is connected to the crystal resonator 40. The movement mechanism 43 is provided to move the crystal resonator 40 close to the sample stage 30 or move the crystal resonator 40 away from the sample stage 30. The control unit 2 is electrically connected to the movement mechanism 43 and can control an operation of the movement mechanism 43.

A distance L2 shown in FIG. 7 is a maximum distance by which the movement mechanism 43 can move. In FIG. 7, a state is shown in which the movement mechanism 43 approaches the sample stage 30 by a distance ΔL2, and a distance between the sample stage 30 and the crystal resonator 40 is shown as a distance L1′.

In the ion milling device 100, the same sample 50 is not always processed, and the structures implementing the sample 50 are various. In various types of the samples 50, since a scattering distance or the distribution of the scattering direction of the sputtering particles SP are different, an optimum value of the distance L1 between the sample stage 30 and the quartz crystal resonator 40 also differs. When the distance L1 is always a constant value, the adhesion amount Δw of the sputtering particles SP may not be sufficiently obtained depending on the sample 50.

Therefore, by making the distance L1 variable by the movement mechanism 43 as in Embodiment 2, it is possible to obtain the suitable adhesion amounts Δw for various types of samples 50. For example, even when the scattering distance of the sputtering particles SP is short or even when the scattering direction of the sputtering particles SP is divergent, it is possible to prevent a decrease in the adhesion amount Δw if the distance between the sample stage 30 and the crystal resonator 40 is shortened as the distance L1′.

Even in the case of the sample 50 of the same material, a target amount of the ion milling processing may be different. Considering that the ion milling processing is performed on the sample 50 of the same material for the same time, the adhesion amount Δw tends to increase when the crystal resonator 40 is close to the sample stage 30, and tends to decrease when the crystal resonator 40 is far from the sample stage 30.

For example, when the amount of the ion milling processing may be small, it is possible to reach the desired adhesion amount Δw in a shorter time and reach the target value frequency by bringing the crystal resonator 40 close to the sample stage 30. Therefore, the amount of the ion milling processing can be reduced without changing a setting of the processing conditions of the ion milling device 100 for a certain sample 50.

A processing method of the sample 50 according to Embodiment 2 includes step S9 of FIG. 8 in addition to steps S1 to S8 of FIG. 6. In step S9, after the inclined angle θ1 and the inclined angle θ2 are confirmed in step S4, the distance ΔL2 for moving the movement mechanism 43 is set. Accordingly, the distance L1 between the sample stage 30 and the crystal resonator 40 can be adjusted. Thereafter, step S5 and subsequent steps are performed.

### (Modification)

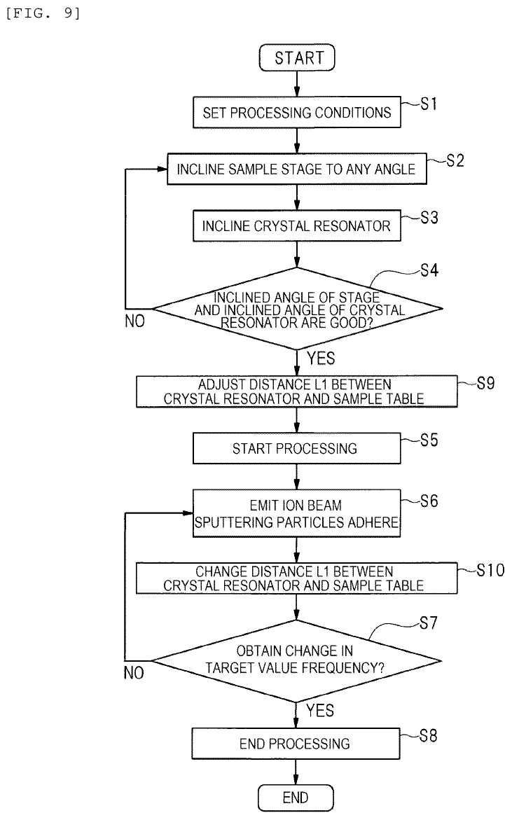

A modification of Embodiment 2 will be described below with reference to FIGS. 9 to 11.

In Embodiment 2, step S9 is added to adjust the distance L1 between the sample stage 30 and the crystal resonator 40 before the emission of the ion beam IB. In the modification, a point of adding step S9 is the same as in Embodiment 2, but as shown in FIG. 9, step S10 for changing the distance L1 is performed between step S6 and step S7.

That is, in the modification, during the emission of the ion beam IB, the control unit 2 can change the distance L1 between the crystal resonator 40 and the sample stage 30 by the movement mechanism 43 according to a change in the frequency output from the crystal resonator 40 to the oscillation circuit 8.

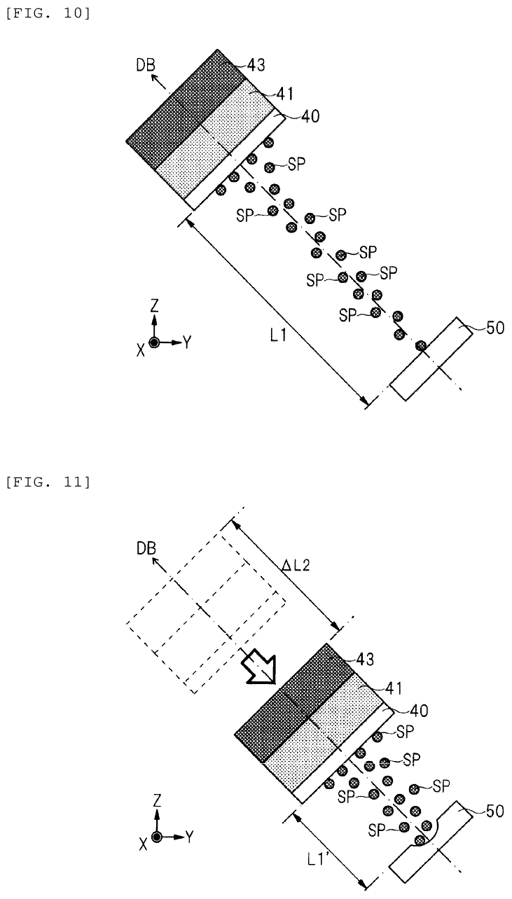

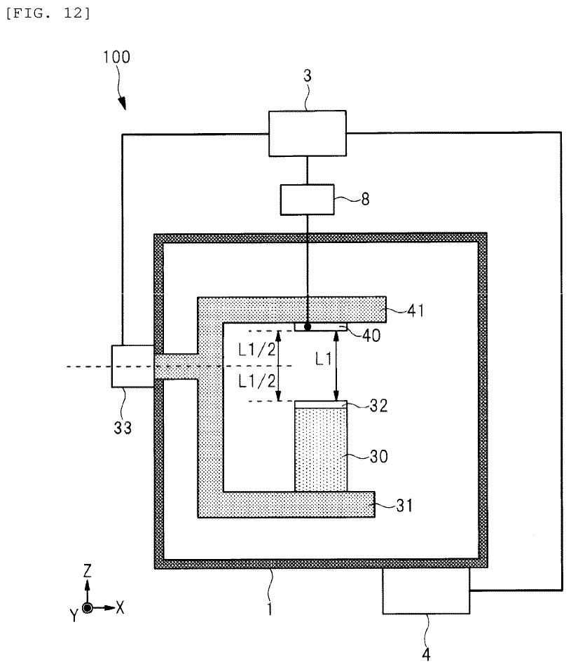

FIG. 10 shows a state immediately after the emission of the ion beam IB and before the change of the distance L1. FIG. 11 shows a state in which the distance L1 is changed to the distance L1′ after a certain period of time elapses from the emission of the ion beam IB.

As shown in FIG. 10, immediately after the emission of the ion beam IB, the sputtering particles SP scatter in the largest amount toward the perpendicular line DB perpendicular to the surface of the sample 50. However, as shown in FIG. 11, the surface of the sample 50 may be processed into a concave shape together with the passage of time. In this case, the sputtering particles SP easily scatter not only on the perpendicular line DB but also in other directions.

Therefore, the adhesion amount per unit time Δw/t becomes gradually constant and then decreases. Therefore, the change amount of the frequency per unit time also gradually becomes constant and then decreases. For example, at a timing at which the change amount of the frequency per unit time becomes constant, the crystal resonator 40 is moved by the distance ΔL2 by the movement mechanism 43, and the crystal resonator 40 is brought close to the sample 50. Accordingly, a large adhesion amount Δw can be obtained in a short time, and the target value frequency can be obtained in a short time.

During the emission of the ion beam IB, the distance L1 can be changed, and the inclined angle θ2 can be changed as in Embodiment 1. Accordingly, it is possible to move the crystal resonator 40 to an optimum position and obtain a large adhesion amount Δw in a short time.

### Embodiment 3

Hereinafter, the ion milling device 100 according to Embodiment 3 will be described with reference to FIG. 12. In the following description, differences from Embodiment 1 will be mainly described, and descriptions of points overlapping those of Embodiment 1 will be omitted.

In Embodiment 1, the first inclining mechanism 31 and the second inclining mechanism 41 are provided as different members and are individually controlled.

As shown in FIG. 12, in Embodiment 3, the first inclining mechanism 31 and the second inclining mechanism 41 are integrated. In other words, the sample stage 30 and the crystal resonator 40 are connected to the same inclining mechanism. Therefore, in order to rotate and move the first inclining mechanism 31 and the second inclining mechanism 41, any one of the motor 33 and the motor 42 may be provided in the ion milling device 100.

As in Embodiment 1, the first inclining mechanism 31 and the second inclining mechanism 41 which are integrated can rotate around the direction (X direction) perpendicular to the central axis DA (Y direction) of the ion beam IB as the rotation axis. Since the first inclining mechanism 31 and the second inclining mechanism 41 are integrated, the rotation axes thereof are necessarily coaxial, and the inclined angle θ2 of the crystal resonator 40 is changed following the change of the inclined angle θ1 of the sample stage 30.

That is, when the first inclining mechanism 31 and the second inclining mechanism 41 which are integrated are prepared, if the inclined angle θ1 and the inclined angle θ2 are designed to be the same in advance, the inclined angle θ2 is always the same as the inclined angle θ1.

In Embodiment 3, the inclined angle θ1 and the inclined angle θ2 cannot be individually controlled, and for example, the crystal resonator 40 can always be located on the perpendicular line DB if the inclined angle θ2 is always the same as the inclined angle θ1. If only one of the inclined angle θ1 and the inclined angle θ2 is adjusted, there is no need to adjust the other. That is, since either step S2 or step S3 and step S4 in FIG. 6 can be omitted, an operation time for the ion milling processing can be shortened.

Further, the movement mechanism 43 described in Embodiment 2 can be connected to the crystal resonator 40 independently of the first inclining mechanism 31 and the second inclining mechanism 41 which are integrated. Accordingly, even in Embodiment 3, the distance L1 between the sample stage 30 and the crystal resonator 40 can be made variable, and the same effects as those of Embodiment 2 can be obtained.

The rotation axes of the first inclining mechanism 31 and the second inclining mechanism 41 are preferably provided at a position at which the distance from the sample stage 30 is the same as the distance from the crystal resonator 40. That is, the rotation axes are preferably provided at a position (distance L1/2) which is half the distance L1.

Although the invention has been specifically described based on the embodiments, the invention is not limited to the embodiments, and various modifications can be made without departing from the gist of the invention.

### REFERENCE SIGNS LIST

100: ion milling device
1: sample chamber
2: control unit
3: display unit
4: vacuum exhaust unit
5: high voltage unit
6: gas supply unit
7: pipe
8: oscillation circuit
20: ion source
21: first cathode electrode
22: second cathode electrode
23: anode electrode
24: permanent magnet
25: acceleration electrode
30: sample stage
31: first inclining mechanism for sample stage
32: sample table
33: motor of first inclining mechanism
40: crystal resonator
41: second inclining mechanism for crystal resonator
42: motor of second inclining mechanism
43: movement mechanism
50: sample
DA: central axis of ion beam
DB: perpendicular line perpendicular to surface of sample
IB: ion beam
SP: sputtering particles

1. An ion milling device comprising:
an ion source configured to emit an ion beam;
a sample stage configured to allow a sample to be placed thereon;
a first inclining mechanism connected to the sample stage and configured to adjust an inclined angle of the sample stage;
a crystal resonator;
an oscillation circuit electrically connected to the crystal resonator and configured to vibrate the crystal resonator and receive a frequency output from the crystal resonator;
a second inclining mechanism connected to the crystal resonator and configured to adjust an inclined angle of the crystal resonator; and
a control unit electrically connected to the ion source, the first inclining mechanism, the oscillation circuit, and the second inclining mechanism and configured to control operations of the ion source, the first inclining mechanism, the oscillation circuit, and the second inclining mechanism.

2. The ion milling device according to claim 1, wherein
the first inclining mechanism and the second inclining mechanism are configured to rotate around a direction perpendicular to a central axis of the ion beam as a rotation axis.

3. The ion milling device according to claim 2, wherein
a rotation axis of the first inclining mechanism and a rotation axis of the second inclining mechanism are coaxial.

4. The ion milling device according to claim 1, wherein
when the sample is placed on the sample stage, the control unit adjusts the inclined angle of the crystal resonator by the second inclining mechanism such that the crystal resonator is located on a perpendicular line perpendicular to a surface of the sample.

5. The ion milling device according to claim 4, wherein
during processing on the sample, the ion beam is emitted from the ion source to the sample, sputtering particles are generated from the sample, a part of the generated sputtering particles adheres to the crystal resonator, the frequency output from the crystal resonator to the oscillation circuit changes depending on an amount of the sputtering particles adhered to the crystal resonator, and when the frequency reaches a target value frequency, the control unit controls the ion source to stop emission of the ion beam.

6. The ion milling device according to claim 5, wherein
the control unit is configured to change the inclined angle of the crystal resonator by the second inclining mechanism according to a change in the frequency output from the crystal resonator to the oscillation circuit during the emission of the ion beam.

7. The ion milling device according to claim 1, wherein
a movement mechanism configured to move the crystal resonator close to the sample stage or move the crystal resonator away from the sample stage is connected to the crystal resonator, and
the control unit is electrically connected to the movement mechanism and is configured to control an operation of the movement mechanism.

8. The ion milling device according to claim 7, wherein
the control unit is configured to change a distance between the crystal resonator and the sample stage by the movement mechanism according to a change in the frequency output from the crystal resonator to the oscillation circuit during emission of the ion beam.

9. The ion milling device according to claim 1, wherein
the first inclining mechanism and the second inclining mechanism are integrated, and
the inclined angle of the crystal resonator is changed following a change in the inclined angle of the sample stage.
